(19) United States
(12) Patent Application Publication
(10) Pub. No.: US 2008/0157133 A1
(43) Pub. Date: Jul. 3, 2008

(54) Semiconductor Device and Fabricating Method Thereof

(76) Inventor: JAE WON HAN, Soowon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/923,440

(22) Filed: Oct. 24, 2007

(30) Foreign Application Priority Data
Dec. 27, 2006 (KR) 10-2006-0135748

(51) Int. Cl. H01L 31/113; H01L 31/18

(52) U.S. Cl. 257/290; 438/70; 438/98; 257/E31.083; 257/E21.477; 257/E21.459

(57) ABSTRACT

A semiconductor device and a fabricating method thereof are provided. A first device having a photodiode cell can be disposed adjacent to a second device having a transistor, and a connection electrode can electrically connect the first device and the second device.

### CROSS-REFERENCE TO RELATED APPLICATION

The present invention claims the benefit under 35 U.S.C. §119 of Korean Patent Application No. 10-2006-0135748, filed Dec. 27, 2006, which is hereby incorporated by reference in its entirety.

### BACKGROUND

A complimentary metal oxide semiconductor (CMOS) image sensor (CIS) generally includes a photodiode region for receiving a light signal and converting it into an electric signal, and a transistor region for processing the electric signal.

In a related art semiconductor device, the photodiode region and the transistor region are often simultaneously implemented onto a single wafer.

Using this related art method, the distance from a microlens to a photodiode often increases due to a back-end-of-line (BEOL) metal line or other structure, which may be form on the transistor region. Accordingly, loss of a light signal incident onto the photodiode region can occur.

Additionally, related art CIS-fabricating methods typically perform lithography processes where the relatively large photodiode region and the relatively small transistor region are simultaneously processed. This can lead to many defects in the photodiode region during the process of forming a transistor. Thus, the characteristics of the CIS can be degraded.

Furthermore, related art CIS-fabricating methods form microlenses with a long distance between the microlens and the photodiode. Moreover, regions where incident light may be lost can also form because the transistor region exists with the photodiode region in the single CIS.

Thus, there exists a need in the art for an improved semiconductor device and fabricating method thereof.

### BRIEF SUMMARY

Embodiments of the present invention provide a semiconductor device and a fabricating method thereof. A system-level, highly-integrated device can be fabricated while the manufacturing process can be simplified and more efficient.

In an embodiment, a semiconductor device can include a first device having a photodiode cell, a second device disposed adjacent to the first device and having a transistor, and a connection electrode electrically connecting the first device and the second device.

A method for fabricating a semiconductor device can include: preparing a first device with a photodiode cell and a second device with a transistor; arranging the first device and the second device adjacent to each other; and electrically connecting the photodiode cell to the second device.

### BRIEF DESCRIPTION OF THE DRAWINGS

FIG. 1 is a top view of a System by Interconnection (SbI) scheme according to an embodiment of the present invention.

FIG. 2 is a cross-sectional view of a SbI scheme according to an embodiment of the present invention.

FIGS. 3 to 6 are views illustrating a method for fabricating a semiconductor device according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

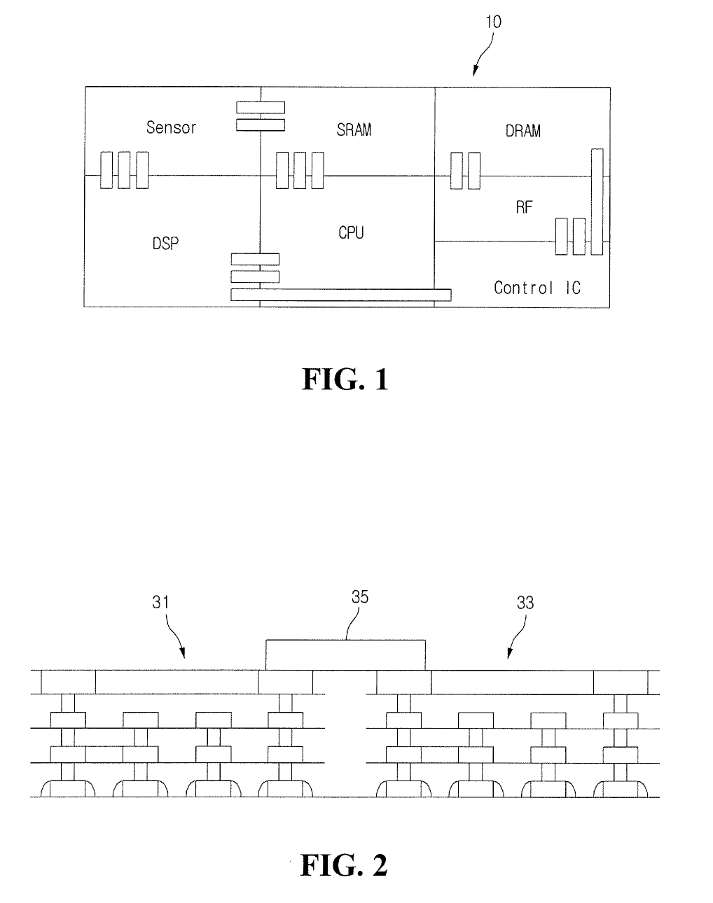

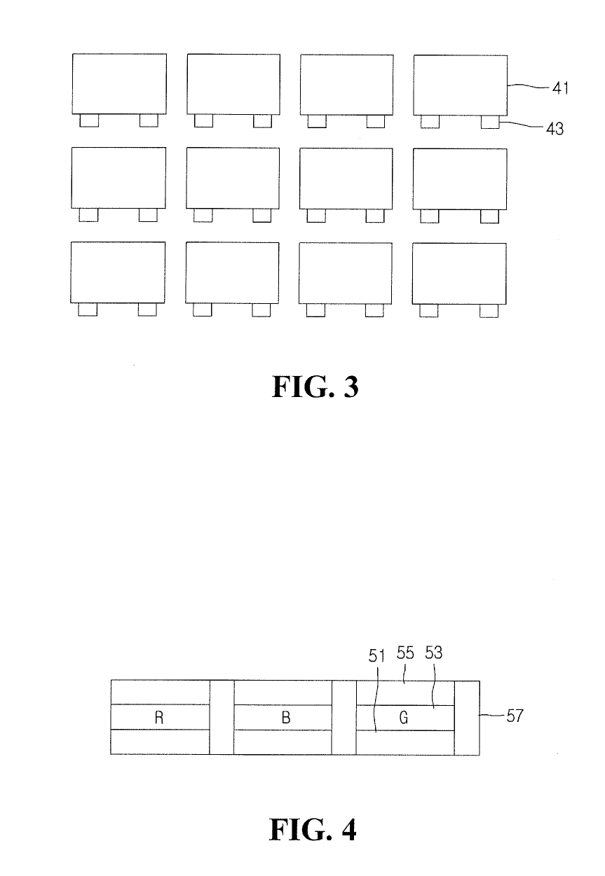

FIGS. 1 and 2 illustrate a System by Interconnection (SbI) scheme according to an embodiment of the present invention.

Referring to FIGS. 1 and 2, a SbI scheme is a method for integrating unit devices fabricated on different wafers through connection electrodes. Each unit device can be, independently, a Central Processing Unit (CPU), Static Read Access Memory, Dynamic Read Access Memory, Flash Memory, a Logic Device, a Power Integrated Circuit (IC), a Control IC, a Sensor Chip, Logic Large Scale Integrated (LSI), Analog LSI, a Mixed Mode Integrated Circuit (MM IC), a CMOS Radio Frequency IC (CMOS RF-IC), a Micro Electro Mechanical Sensor (MEMS) Chip, or any other appropriate device known in the art.

In an embodiment, a first device 31 and a second device 33 can be separately fabricated and then electrically connected to each other through a connection electrode 35. In a further embodiment, additional devices can be fabricated and then electrically connected to the first and second devices 31 and 33 and to each other through additional connection electrodes. Any suitable number of devices can be fabricated and connected.

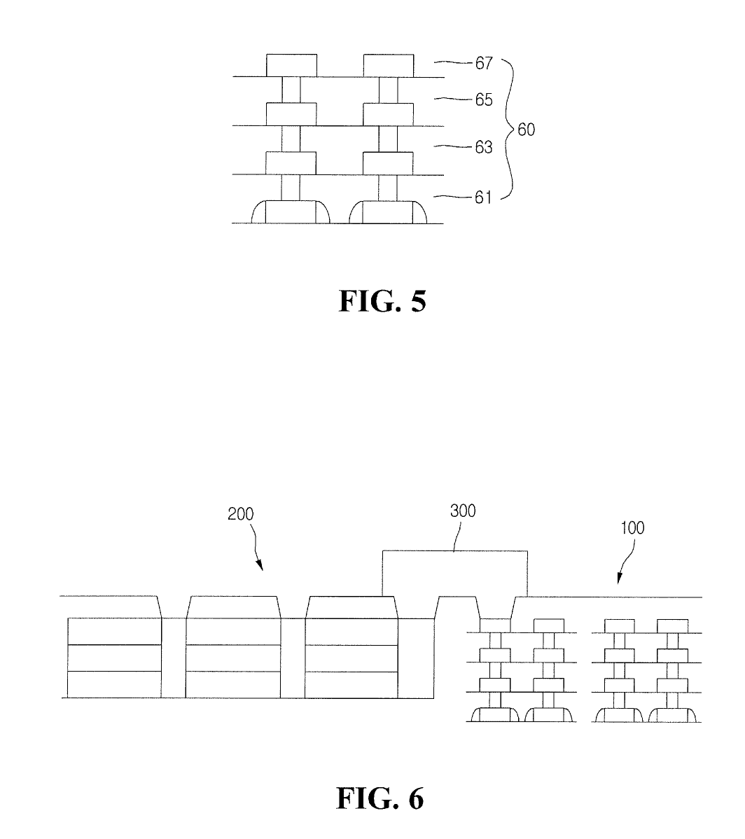

FIGS. 3 to 6 illustrate a method for fabricating a semiconductor device according to an embodiment.

Referring to FIG. 3, a first device with a photodiode cell 41 can be fabricated. In an embodiment, the first device can also have a pad electrode 43.

The photodiode cell 41 is a region where a photodiode can be formed. The pad electrode 43 can be used to transfer an electric signal generated by the photodiode to a transistor region which can be electrically connected to the pad electrode 43.

In an embodiment, the first device can have a stacked structure as shown in FIG. 4.

Referring to FIG. 4, a photodiode cell 51 can be formed on a semiconductor substrate (not shown), and a color filter 53 can be formed on the photodiode cell 51. A passivation layer 55 can be formed on the color filter 53, and a pad electrode 57 can be electrically connected to the photodiode cell 51. Although not shown in the figure, the photodiode cells 51 with connected pad electrode 57 can be spaced apart from each other.

In an embodiment, the pad electrode 57 can be formed after forming the photodiode cell 51 and before forming the color filter 53 and the passivation layer 55. In addition, after forming the color filter 53 and the passivation layer 55, a pad open process can be performed to expose the pad electrode 57.

The pad electrode 57 can be formed of any suitable material known in the art, for example, tungsten (W), copper (Cu), aluminum (Al), silver (Ag), gold (Au), or any combination thereof. The pad electrode 57 can be formed by a chemical vapor deposition (CVD) process, a physical vapor deposition (PVD) process, an evaporation process, an electrochemical plating (ECP) process, or any other appropriate method known in the art. The pad electrode 57 can include a barrier metal; and the banner metal can be formed of any suitable material known in the art, for example, tantalum nitride (TaN), tantalum (Ta), titanium nitride (TiN), titanium (Ti), titanium silicon nitride (TiSiN), or any combination thereof The barrier metal of the pad electrode 57 can be formed by a CVD process, a PVD process, an atomic layer deposition (ALD) process, or any other appropriate method known in the art.

FIG. 5 is a cross-sectional view of a second device having a transistor region. The transistor region can be formed by any appropriate method known in the art.

Referring to FIG. 5, a second device 60 including a transistor layer 61, and at least one metal layer (for example, a first metal layer 63, a second metal layer 65, and a third metal layer 67) can be fabricated.

The transistor layer 61 and the metal layer or layers (for example, the first metal layer 63, the second metal layer 65, and the third metal layer 67) can form a signal processing circuit. Although three metal layers 63, 65 and 67 are illustrated in FIG. 5, the second device 60 can include any suitable number of metal layers.

Any suitable number of transistors can be formed for each photodiode according to design of the semiconductor device. For example, the number of the transistors can be 1, 2, 3, 4, or more. In addition, since the region where the photodiode cell is formed can be wide, many transistors can be formed to improve the characteristics of the semiconductor device.

FIG. 6 is a cross-sectional view showing a semiconductor device fabricated using the SbI scheme according to an embedment. A first device 100 having a processing circuit and a second device 200 having a photodiode cell can be integrated by connecting them using the SbI scheme.

Referring to FIG. 6, the semiconductor device can include a first device 100 with a transistor, a second device 200 with a photodiode cell, and a connection electrode 300. The connection electrode 300 can connect the transistor of the first device 100 to the photodiode cell of the second device 200.

In an embodiment, the connection electrode 300 can be electrically connected to the photodiode cell through a pad electrode in the second device 200. The connection electrode 300 can be connected to the uppermost metal layer of the first device 100. In a further embodiment, the uppermost surface of the first device 100 can be approximately even with the uppermost surface of the second device 200.

The connection electrode 300 can be formed of any suitable material known in the art, for example, tungsten (W), copper (Cu), aluminum (Al), silver (Ag), gold (Au), or any combination thereof The connection electrode 300 can be formed by a chemical vapor deposition (CVD) process, a physical vapor deposition (PVD) process, an evaporation process, an electrochemical plating (ECP) process, or any other appropriate method known in the art. The connection electrode 300 can include a barrier metal, and the barrier metal can be formed of any suitable material known in the art, for example, tantalum nitride (TaN), tantalum (Ta), titanium nitride (TiN), titanium (Ti), titanium silicon nitride (TiSiN), or any combination thereof. The barrier metal of the connection electrode 300 can be formed by a CVD process, a PVD process, an ALD process, or any other appropriate method known in the art.

In further embodiments, any suitable number of devices can be included beyond the first device 100 and the second device 200. Each device can be electrically connected to all other devices by using connecting electrodes.

In embodiments of the present invention, the first device with the photodiode cell and the second device for transistor and metal line can be formed in separate processes. Therefore, even if an error were to occur during the process of forming the first device, the second device can still be used. Similarly, if an error were to occur during the process of forming the second device, the first device can still be used.

Additionally, a high-performance photodiode cell can be fabricated without having to go through the processes of forming the transistor, leading to a decreased incidence of defects in the photodiode cell.

Furthermore, the photodiode cell can be exposed to incident light relatively directly. Since an interlayer insulating layer and a metal line layer do not need to be formed during the same process that forms the photodiode cell, it can be unnecessary to form a separate microlens on a color filter.

Moreover, the manufacturing process of the semiconductor device can be simplified and more efficient while fabricating a system-level highly-integrated device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a first device including a photodiode cell;
a second device disposed adjacent to the first device and including a transistor; and
a connection electrode electrically connecting the first device to the second device.

2. The semiconductor device according to claim 1, wherein the first device comprises:
the photodiode cell on a semiconductor substrate;
a color filter on the photodiode cell; and
a pad electrode electrically connected to the photodiode cell.

3. The semiconductor device according to claim 2, wherein the connection electrode is electrically connected to the photodiode cell through the pad electrode.

4. The semiconductor device according to claim 2, wherein the pad electrode comprises tungsten (W), copper (Cu), aluminum (Al), silver (Ag), or gold (Au).

5. The semiconductor device according to claim 1, wherein the second device comprises:
a transistor layer including the transistor on the semiconductor substrate; and
at least one metal layer on the transistor layer.

6. The semiconductor device according to claim 1, wherein the connection electrode comprises tungsten (W), copper (Cu), aluminum (Al), silver (Ag), or gold (Au).

7. The semiconductor device according to claim 1, wherein the connection electrode comprises a barrier metal.

8. The semiconductor device according to claim 7, wherein the barrier metal comprises tantalum nitride (TaN), tantalum (Ta), titanium nitride (TiN), titanium (Ti), or titanium silicon nitride (TiSiN).

9. The semiconductor device according to claim 1, wherein an uppermost surface of the first device is approximately even with an uppermost surface of the second device.

10. A method for fabricating a semiconductor device, comprising:
forming a first device including a photodiode cell;
forming a second device including a transistor;
arranging the first device and the second device adjacent to each other; and
electrically connecting the photodiode cell to the second device.

11. The method according to claim 10, wherein electrically connecting the photodiode cell to the second device comprises forming a connection electrode.

12. The method according to claim 11, wherein the connection electrode comprises tungsten (W), copper (Cu), aluminum (Al), silver (Ag), or gold (Au).

13. The method according to claim 11, wherein forming a connection electrode comprises performing a chemical vapor deposition (CVD) process, a physical vapor deposition (PVD) process, an evaporation process, or an electrochemical plating (ECP) process.

14. The method according to claim 11, wherein forming the connection electrode comprises forming a barrier metal.

15. The method according to claim 14, wherein forming the banner metal comprises performing a CVD process, a PVD process, or an atomic layer deposition (ALD) process.

16. The method according to claim 14, wherein the barrier metal comprises tantalum nitride (TaN), tantalum (Ta), titanium nitride (TiN), titanium (Ti), or titanium silicon nitride (TiSiN).

17. The method according to claim 10, wherein forming the first device including the photodiode cell comprises:
forming the photodiode cell on a semiconductor substrate;
forming a color filter on the photodiode cell; and
forming a pad electrode electrically connected to the photodiode cell.

18. The method according to claim 11, wherein electrically connecting the photodiode cell to the second device comprises forming a connection electrode, and wherein the connection electrode is electrically connected to the photodiode cell through the pad electrode.

19. The method according to claim 17, wherein the pad electrode comprises tungsten (W), copper (Cu), aluminum (Al), silver (Ag), or gold (Au).

20. The method according to claim 10, wherein arranging the first device and the second device adjacent to each other comprises arranging the first device and the second device such that an uppermost surface of the first device is approximately even with an uppermost surface of the second device.
